(19) United States
(12) Patent Application Publication
(10) Pub. No.: US 2023/0127088 A1
(43) Pub. Date: Apr. 27, 2023

(54) SEAL FOR THERMAL INTERFACE MATERIAL OF POWER ELECTRONICS MODULES

(71) Applicant: Carrier Corporation, Palm Beach Gardens, FL (US)

(72) Inventors: Konstantin Borisov, Avon, CT (US); William Tony Slay, Chickamauga, GA (US); Ismail Agirman, Southington, CT (US)

(21) Appl. No.: 17/961,694

(22) Filed: Oct. 7, 2022

Related U.S. Application Data
(60) Provisional application No. 63/270,888, filed on Oct. 22, 2021.

(51) Int. Cl. H05K 7/20

(52) U.S. Cl. CPC H05K 7/20509; H05K 7/20927

(57) ABSTRACT

A heat exchanger assembly includes a heat exchanger and a power electronics module mounted to the heat exchanger. The power electronics module is thermally coupled to the heat exchanger at a heat sink interface. A thermal interface material is arranged between the heat sink interface and a surface of the heat exchanger and a gasket arranged between the heat sink interface and the surface of the heat exchanger.

### CROSS-REFERENCE TO RELATED APPLICATIONS

This application claims the benefit of U.S. Provisional Application No. 63/270,888 filed Oct. 22, 2021, the disclosure of which is incorporated herein by reference in its entirety.

### BACKGROUND

Exemplary embodiments pertain to the art of heat exchangers, and more particularly, the present disclosure relates to an interface for cooling power electronics that are mounted to a heat exchanger.

Power electronic devices such as motor drives can generate waste heat during operation based on the efficiency of the device. Additionally, when the power electronic devices heat up, their efficiency can degrade adding to the amount of heat they generate. When configured into a refrigeration system, effective thermal integration of these devices can be important aspect to the system's overall efficiency and reliability. Consequently, a goal of the system integrator is to maintain these components within a range of operating temperatures which will maximize the system efficiency. Accordingly, there remains a need in the art for heat exchangers configured to closely integrate with power electronic devices which can maintain optimal temperatures for these components under a variety of load conditions.

### BRIEF DESCRIPTION

According to an embodiment, a heat exchanger assembly includes a heat exchanger and a power electronics module mounted to the heat exchanger. The power electronics module is thermally coupled to the heat exchanger at a heat sink interface. A thermal interface material is arranged between the heat sink interface and a surface of the heat exchanger and a gasket arranged between the heat sink interface and the surface of the heat exchanger.

In addition to one or more of the features described herein, or as an alternative, further embodiments the gasket surrounds at least a portion of the thermal interface material.

In addition to one or more of the features described herein, or as an alternative, further embodiments the gasket defines a boundary that restricts movement of the thermal interface material relative to the heat sink interface and the surface of the heat exchanger.

In addition to one or more of the features described herein, or as an alternative, further embodiments the gasket extends about at least a portion of a periphery of the heat sink interface.

In addition to one or more of the features described herein, or as an alternative, further embodiments the gasket extends about an entire periphery of the heat sink interface.

In addition to one or more of the features described herein, or as an alternative, further embodiments the gasket is compressed to form a seal between the heat sink interface and the surface of the heat exchanger.

In addition to one or more of the features described herein, or as an alternative, further embodiments the surface of the heat exchanger has a substantially planar configuration and the gasket is positioned in overlapping arrangement with the surface.

In addition to one or more of the features described herein, or as an alternative, further embodiments the surface of the heat exchanger has a gasket groove formed therein, the gasket being arranged within the gasket groove.

In addition to one or more of the features described herein, or as an alternative, further embodiments only a portion of the gasket extends beyond the surface of the heat exchanger.

In addition to one or more of the features described herein, or as an alternative, further embodiments the gasket has a substantially continuous tube-like configuration.

In addition to one or more of the features described herein, or as an alternative, further embodiments the gasket has a substantially planar configuration.

In addition to one or more of the features described herein, or as an alternative, further embodiments the thermal interface material is thermal grease.

In addition to one or more of the features described herein, or as an alternative, further embodiments the power electronics module is mounted in a vertical plane.

In addition to one or more of the features described herein, or as an alternative, further embodiments the heat exchanger further comprises: a housing having an inlet and an outlet formed therein; a fluid circuit arranged within the housing and extending between the inlet and the outlet; and a fluid circulating through the fluid circuit.

In addition to one or more of the features described herein, or as an alternative, further embodiments the fluid circuit further comprises: an inlet manifold; an outlet manifold; and a plurality of fluid passages connecting the inlet manifold and the outlet manifold.

In addition to one or more of the features described herein, or as an alternative, further embodiments at least one of the inlet manifold, the outlet manifold, and the plurality of fluid passages is formed as a recess formed in the housing.

In addition to one or more of the features described herein, or as an alternative, further embodiments the inlet is disposed below the outlet such that during operation a flow direction of a refrigerant through the inlet manifold and the outlet manifold opposes gravity.

In addition to one or more of the features described herein, or as an alternative, further embodiments the housing further comprises a first housing portion and a second housing portion joined along corresponding mating surfaces.

In addition to one or more of the features described herein, or as an alternative, further embodiments at least one of the first housing portion and the second housing portion is a plate.

### BRIEF DESCRIPTION OF THE DRAWINGS

The following descriptions should not be considered limiting in any way. With reference to the accompanying drawings, like elements are numbered alike:

FIG. 1 is a schematic illustration of an exemplary heat exchanger having and power electronic modules mounted thereto according to an embodiment;

FIG. 2 is a schematic illustrations of the A-A cross section of a heat exchanger of FIG. 1 according to an embodiment;

FIG. 3 is a front view of an exemplary heat exchanger having a plurality to of power electronic mounted thereto according to an embodiment;

FIG. 4 is a cross-sectional view of a portion of the heat exchanger of FIG. 3 taken through a power electronic module according to an embodiment; and

FIG. 5 is a cross-sectional view of a portion of the heat exchanger of FIG. 3 taken through a power electronic module according to another embodiment.

### DETAILED DESCRIPTION

A detailed description of one or more embodiments of the disclosed apparatus and method are presented herein by way of exemplification and not limitation with reference to the Figures.

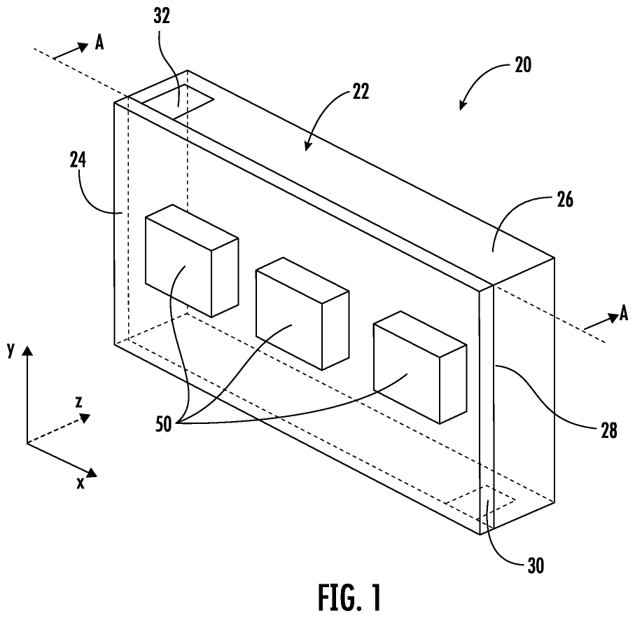

With reference now to FIG. 1, a schematic illustration of an example of a heat exchanger 20 is illustrated according to an embodiment. As shown, the heat exchanger 20 includes a housing 22 formed from a heat conductive material, such as a metal material. For example, the housing 22 may be formed from any suitable metal, e.g., aluminum, aluminum alloy, steel, steel alloy, copper, copper alloy, or the like. In the illustrated, non-limiting embodiment, the housing 22 is formed from a plurality of housing portions, such as a first housing portion 24, and a second housing portion 26, joined along corresponding mating surfaces to form a seam 28 therebetween. In such embodiments, the first and second housing portions 24, 26 can abut one another along a side and can be joined using any suitable means such as brazing, welding, clamping, compressing, bolting, and the like. Although two housing portions 24, 26 are illustrated in the exemplary embodiments, it should be understood that a housing 22 formed from any number of housing portions including a single housing portion, or more than two housing portions for example, are within the scope of the disclosure.

The mating surfaces of the first and second housing portions 24, 26 may be configured to correspond to one another, e.g., to fit together to seal a fluid circuit therebetween (the fluid circuit to be described in more detail below). In an embodiment, the mating surfaces of the first and second housing portions 24, 26 include precision surfaces formed from a process having highly accurate and precise dimensional control, such as through computer numerical control (CNC) machining process and/or net shape, or near net shape manufacturing process. Optionally a sealing material can be disposed between the first and second housing portions 24, 26 to aide in preventing leakage from the fluid circuit.

As shown in FIG. 1, the first and second housing portions 24, 26 can have different thicknesses, measured along the z-axis. In the illustrated, non-limiting embodiment, a thickness of the first housing portion 24 is greater than a thickness of the second housing portion. However, embodiments where the first housing portion 24 and the second housing portion 26 are equal in thickness, or alternatively, where a thickness of the second housing portion 26 is greater than a thickness of the first housing portion 24 are also within the scope of the disclosure. In an embodiment, each of the first housing portion 24 and the second housing portion 26 is formed as a substantially solid plate. However, embodiments where one or more of the housing portions 24, 26 has another configuration are also contemplated herein.

The heat exchanger 20 includes a fluid circuit formed between the first and second housing portions 24, 26. The fluid circuit includes a fluid inlet 30 and fluid outlet 32 formed in the housing 22. The fluid inlet 30 and the fluid outlet 32 can be any shape, such as in the depth dimension (e.g., in the z-x plane of the attached figure), including the shape of a circle, oval, triangular, square, rectangular, or any simple polygonal shape or portion thereof. Further, the perimeter of one or both of the fluid inlet 30 and the fluid outlet 32 can be formed by a recess in at least one or both of the housing portions 24, 26. The recess may extend to an edge of a respective housing portion, may be arranged centrally relative to a housing portion, or may overlap with the seam 28 defined between two adjacent housing portions 24, 26.

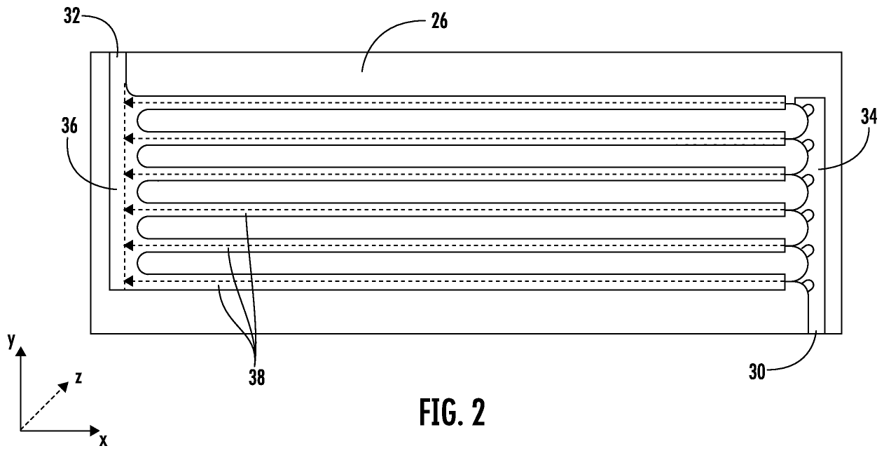

An example of the fluid circuit is best illustrated in the cross-sectional view of the heat exchanger 20 shown in FIG. 2. In addition to the inlet 30 and the outlet 32, the fluid circuit may include a first or inlet manifold 34, a second or outlet manifold 36, and a plurality of fluid passages 38 connecting the first and second manifolds 34, 36. The fluid inlet 30 can be configured to connect a first heat transfer fluid (e.g., refrigerant) source, such as a condenser of a vapor compression system for example, to the inlet manifold using any suitable mechanical connection. Similarly, the fluid outlet 32 can be configured to connect a first heat transfer fluid sink, such as an evaporator of a vapor compression system for example, to the outlet manifold using any suitable mechanical connection (e.g., compression coupling, brazing, welding, and the like). In an embodiment, the fluid inlet 30 is disposed vertically below the fluid outlet 32 such that during operation of the heat exchanger 20, a flow direction of a refrigerant through the inlet and outlet manifolds 34, 36 opposes gravity.

One or more of the inlet manifold 34, the outlet manifold 36, and the plurality of fluid passages 38 is formed as a recess in at least one of the first housing portion 24 and the second housing portion 26. In an embodiment, the inlet manifold 34, the outlet manifold 36, and the plurality of fluid passages 38 are formed as a plurality of connected recesses in at least one housing portion, such as the second housing portion 26 for example. Accordingly, the plurality of recesses form the fluid circuit disposed between the first and second housing portions 24, 26 when the housing portions 24, 26 are joined. For example, a first housing portion 24 having a plurality of connected recesses can be joined to a flat, second housing portion 26 that does not have any recesses formed therein. In another embodiment, a first housing portion 24 and a second housing portion 26 can each have a plurality of connected recesses which mirror one another such that when the first and second housing portions 24, 26 are joined, the connected recesses form the fluid circuit. The plurality of connected recesses can have any shape in the depth dimension (e.g., as projected onto a z-y plane of the attached figures, into the plate), including semi-circular, semi-oval, triangular, square, rectangular, or any simple polygonal shape or portion thereof.

The mating surfaces of the first and second housing portions 24, 26 can substantially border the plurality of connected recesses. Optionally, the mating surfaces can include raised or recessed portions, or other engagement features to aid in alignment of the housing portions 24, 26 prior to joining.

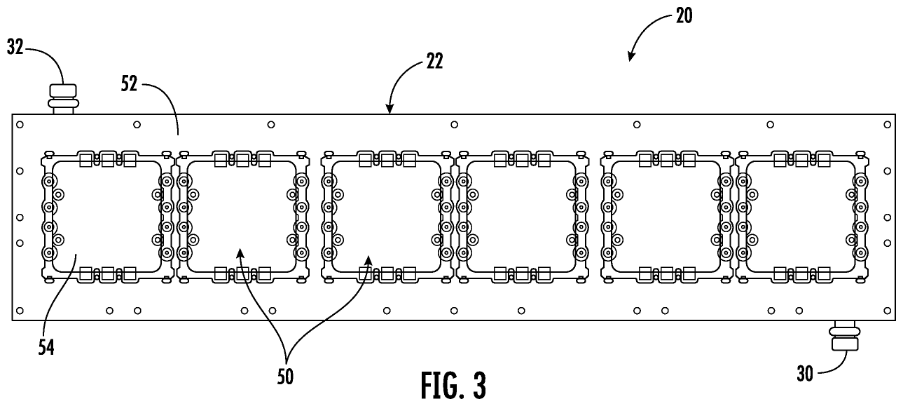

A heat exchanger 20 as described herein can be used, such as in a vapor compression system for example, to cool one or more power electronic modules 50. As described herein, a heat exchanger 20 having one or more power electronics modules 50 mounted thereon may be considered a heat exchanger assembly. The term “power electronic module” as used herein can refer to any electronic component which can provide a controlled output power by modulating and/or converting a supplied input power (e.g., a variable frequency drive, power rectifier, power converter, and the like). Such a power electronic module 50 can be used to control the speed of a compressor and/or the speed of the fan of a vapor compression system (e.g., chiller) based on various predetermined system conditions. With reference again to FIG. 1, and further reference to FIGS. 3-5, in an embodiment, one or more power electronic modules 50 are mounted directly to a surface 52 of at least one of the plurality of housing portions, such as first housing portion 24 for example. In the illustrated, non-limiting embodiment, the plurality of power electronics modules 50 are mounted to a vertically oriented surface of the housing 22. However, embodiments where one or more power electronics modules 50 are mounted to a surface of a housing 22 having a non-vertical orientation, such as a horizontal surface for example, are also within the scope of the disclosure. The power electronic modules 50 may be mounted to the housing 22 of the heat exchanger 20 via one or more fasteners in such a way that facilitates the transfer of thermal energy away from the power electronics module 50.

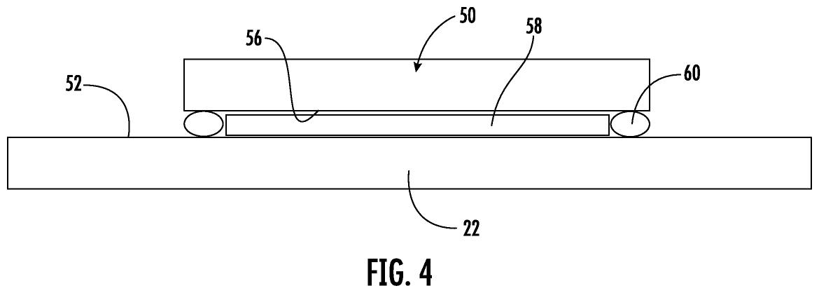

The one or more power electronics modules 50 may include a printed circuit board 54 on which various other electrical components (not shown) are mounted (e.g., protection, signal processing, and filtering related components). The reliability and life of the one or more power electronics modules 50 can depend upon precluding such electrical components from operating at high temperatures and/or precluding their exposure to thermal shock. Because electrical components inside the power electronics modules 50 can generate a large amount of heat, each of the power electronics modules 50 has a heat sink interface 56 (see FIG. 4) which is designed for attachment to a heat sink, such as the heat exchanger 20. When the power electronics modules 50 are secured in thermal communication with the heat exchanger 20, the heat generated by the power electronics module 50 is at least partially removed through the heat sink interface 56 to keep the one or more power electronics module 50 cooled below its maximum allowable operating temperature (e.g., 150° C.).

A thermal interface material, illustrated schematically at 58, may be positioned between the heat sink interface 56 of a respective power electronics module 50 and the adjacent surface 52 of the housing 22 configured to receive the power electronics module 50. In an embodiment, the thermal interface material 58 is a thermal grease or compound having a high thermal conductivity. However, in other embodiments the thermal interface material may include a multiphase material and/or an elastomeric material such as a thermal pad. In applications where a power electronics module 50 is mounted in a vertical plane relative to a surface 52 of the housing 22 of the heat exchanger 20, the gravitational forces acting on the thermal grease 58 may cause the thermal grease 58 to move or drip relative to the heat sink interface 56. In addition, if condensation collects on the surface 52 of the heat exchanger 20, such as resulting from the heat removal therefrom, the condensation in combination with the gravitational forces may wash the thermal grease 58 away from the heat sink interface 56.

In an embodiment, to prevent this loss or washing away of the thermal interface material 58 at the heat sink interface 56, a gasket 60 is disposed between a portion of the power electronics module 50 and the heat exchanger 20. The gasket 60 may extend about at least a portion of the perimeter of the power electronics module 50 at the heat sink interface 56. In the illustrated, non-limiting embodiment, the gasket 60 extends about an entire periphery of the heat sink interface 56. In such embodiments, the dimensions of the gasket 60 are substantially complementary to, or slightly smaller than, the length and width of a respective power electronics module 50. The gasket 60 may have a substantially continuous tube-like configuration, of alternatively, may have a substantially planar configuration similar to a washer. However, any suitable configuration of a gasket 60 is within the scope of the disclosure.

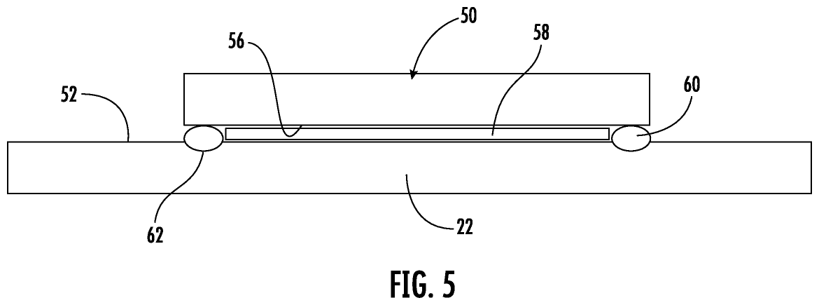

In an embodiment, the surface 52 of the heat exchanger 20 configured to receive the power electronics module 50 is generally planar (see FIG. 4). As a result, the entirety of the gasket 60 is positioned adjacent to and in overlapping arrangement with the surface 52. In another embodiment, best shown in FIG. 5, a gasket groove or recess 62 complementary to the gasket 60 is formed in the surface 52 of the heat exchanger 20. In such embodiments, the gasket 60 is receivable within the gasket groove 62, and therefore only a portion of the gasket 60 protrudes beyond the surface 52 towards the power electronics module 50.

When the power electronics module 50 is installed about the surface 52 of the heat exchanger 20, the gasket 60 may be at least partially compressed, thereby forming a seal between the surface 52 of the heat exchanger 20 and a surface of the power electronics module 50 at the heat sink interface 56. Because the gasket 60 extends about at least a portion of the periphery of the heat sink interface 56, the gasket forms a boundary or outer edge to at least a portion of the thermal interface material 58. Accordingly, the seal formed between the power electronics module 50 and the surface 52 of the heat exchanger 20 by the compressed gaskets 60 forms a boundary that restricts movement of the thermal interface material 58 from adjacent to the heat sink interface 56.

By using a gasket to retain the thermal interface material 58 between the heat sink interface 56 of a power electronics module 50 and a heat exchanger 20, the thermal conductivity between the power electronics module 50 and the heat exchanger 20 is improved, thereby extending the life of the electronic components within the power electronics modules 50.

The term “about” is intended to include the degree of error associated with measurement of the particular quantity based upon the equipment available at the time of filing the application.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

What is claimed is:

1. A heat exchanger assembly comprising:
a heat exchanger;
a power electronics module mounted to the heat exchanger, wherein the power electronics module is thermally coupled to the heat exchanger at a heat sink interface;
a thermal interface material arranged between the heat sink interface and a surface of the heat exchanger; and
a gasket arranged between the heat sink interface and the surface of the heat exchanger.

2. The heat exchanger assembly of claim 1, wherein the gasket surrounds at least a portion of the thermal interface material.

3. The heat exchanger assembly of claim 1, wherein the gasket defines a boundary that restricts movement of the thermal interface material relative to the heat sink interface and the surface of the heat exchanger.

4. The heat exchanger assembly of claim 1, wherein the gasket extends about at least a portion of a periphery of the heat sink interface.

5. The heat exchanger assembly of claim 4, wherein the gasket extends about an entire periphery of the heat sink interface.

6. The heat exchanger assembly of claim 1, wherein the gasket is compressed to form a seal between the heat sink interface and the surface of the heat exchanger.

7. The heat exchanger assembly of claim 1, wherein the surface of the heat exchanger has a substantially planar configuration and the gasket is positioned in overlapping arrangement with the surface.

8. The heat exchanger assembly of claim 1, wherein the surface of the heat exchanger has a gasket groove formed therein, the gasket being arranged within the gasket groove.

9. The heat exchanger assembly of claim 8, wherein only a portion of the gasket extends beyond the surface of the heat exchanger.

10. The heat exchanger assembly of claim 1, wherein the gasket has a substantially continuous tube-like configuration.

11. The heat exchanger assembly of claim 1, wherein the gasket has a substantially planar configuration.

12. The heat exchanger assembly of claim 1, wherein the thermal interface material is thermal grease.

13. The heat exchanger assembly of claim 1, wherein the power electronics module is mounted in a vertical plane.

14. The heat exchanger assembly of claim 1, wherein the heat exchanger further comprises:
a housing having an inlet and an outlet formed therein;
a fluid circuit arranged within the housing and extending between the inlet and the outlet; and
a fluid circulating through the fluid circuit.

15. The heat exchanger assembly of claim 14, wherein the fluid circuit further comprises:
an inlet manifold;
an outlet manifold; and
a plurality of fluid passages connecting the inlet manifold and the outlet manifold.

16. The heat exchanger assembly of claim 15, wherein at least one of the inlet manifold, the outlet manifold, and the plurality of fluid passages is formed as a recess formed in the housing.

17. The heat exchanger assembly of claim 15, wherein the inlet is disposed below the outlet such that during operation a flow direction of a refrigerant through the inlet manifold and the outlet manifold opposes gravity.

18. The heat exchanger assembly of claim 14, wherein the housing further comprises a first housing portion and a second housing portion joined along corresponding mating surfaces.

19. The heat exchanger assembly of claim 18, wherein at least one of the first housing portion and the second housing portion is a plate.
